(19) United States
(12) Patent Application Publication
(10) Pub. No.: US 2024/0355900 A1
(43) Pub. Date: Oct. 24, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventor: Man-Nung Su, Hsinchu (TW)

(73) Assignee: Taiwan Semiconductor Manufacturing Company, Ltd., Hsinchu (TW)

(21) Appl. No.: 18/302,010

(22) Filed: Apr. 18, 2023

(51) Int. Cl. H01L 29/66; H01L 23/00; H01L 23/12; H01L 29/775

(52) U.S. Cl. CPC H01L 29/66439; H01L 23/12; H01L 24/29; H01L 24/32; H01L 24/83; H01L 29/66742; H01L 29/775; H01L 24/94; H01L 29/0673; H01L 29/42392; H01L 2224/29138; H01L 2224/29186; H01L 2224/8301; H01L 2224/83193; H01L 2224/83896; H01L 2224/94; H01L 2924/01014; H01L 2924/0504; H01L 2924/0544; H01L 2924/059

(57) ABSTRACT

A semiconductor device and a forming method thereof are provided. The semiconductor device includes a device layer including a front side and a back side opposite to each other, a bonding layer disposed on the back side of the device layer, and a carrier substrate underlying the bonding layer. The device layer includes source/drain (S/D) structures, semiconductor channel layers connecting the S/D structures, and a gate structure disposed between the S/D structures and around each of the semiconductor channel layers, where the back side is planar and includes the S/D structures and the gate structure.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 17 illustrate schematic perspective views and cross-sectional views of intermediate steps during a process for forming a semiconductor device, in accordance with some embodiments.

FIG. 18 illustrates a schematic cross-sectional view of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the disclosure describe a manufacturing process of a semiconductor device (or a portion of a nanostructure transistor device). The nanostructure transistor device (also referred to as a gate-all-around (GAA) transistor device) may include a gate structure wrapping around the perimeter of one or more nanostructures (i.e. channel regions) for improved control of channel current flow. The embodiments are not limited in this context. The semiconductor device may be included in microprocessors, memories, and/or other integrated circuits (IC). Accordingly, it is understood that additional processes may be provided before, during, and after the illustrated method, and that some other processes may only be briefly described herein. Also, the structures illustrated in the drawings are simplified for a better understanding of the concepts of the present disclosure. For example, although the figures illustrate the structure of the semiconductor device, it is understood the semiconductor device may be part of an IC that further includes a number of other devices such as resistors, capacitors, inductors, fuses, etc.

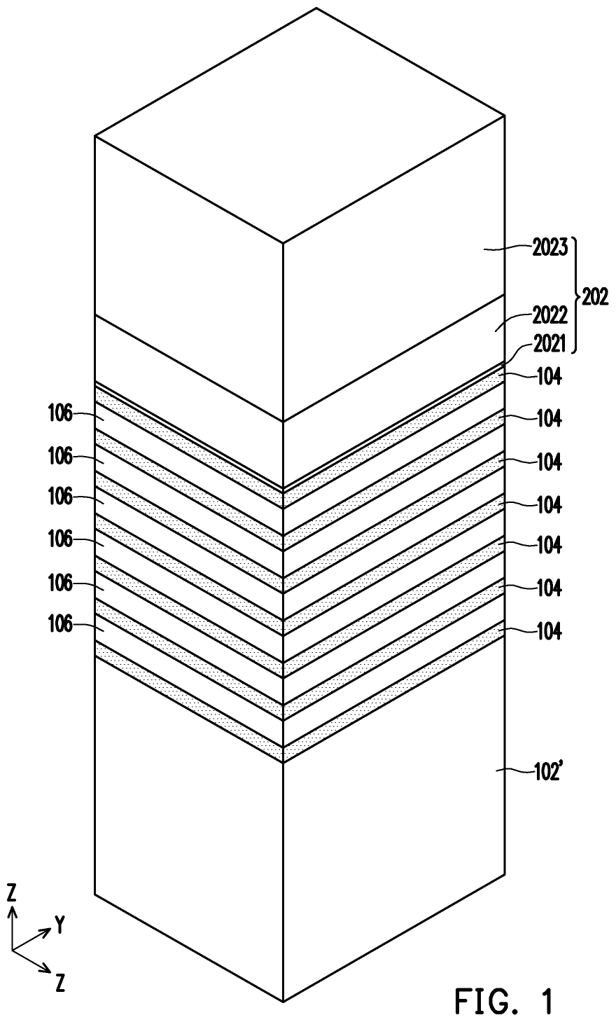

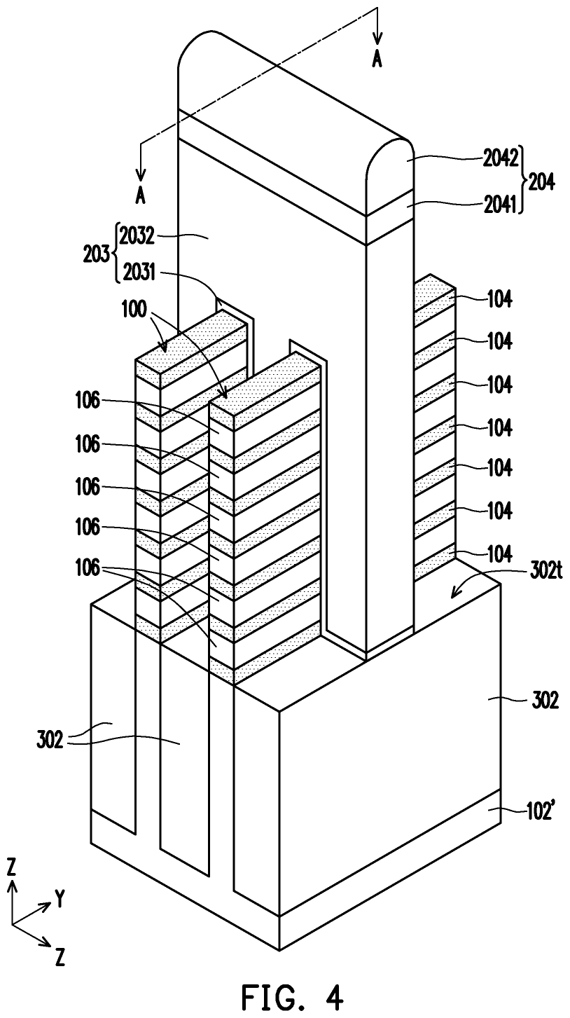

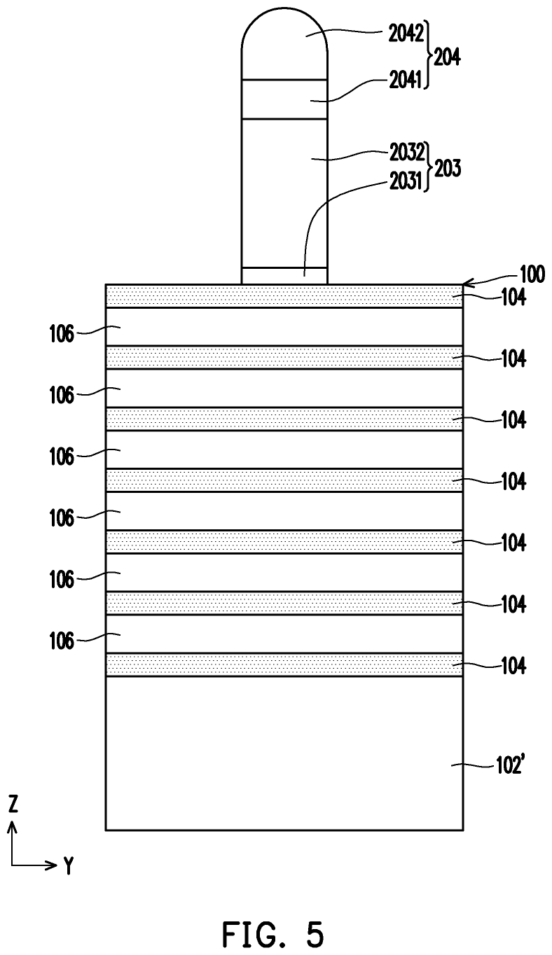

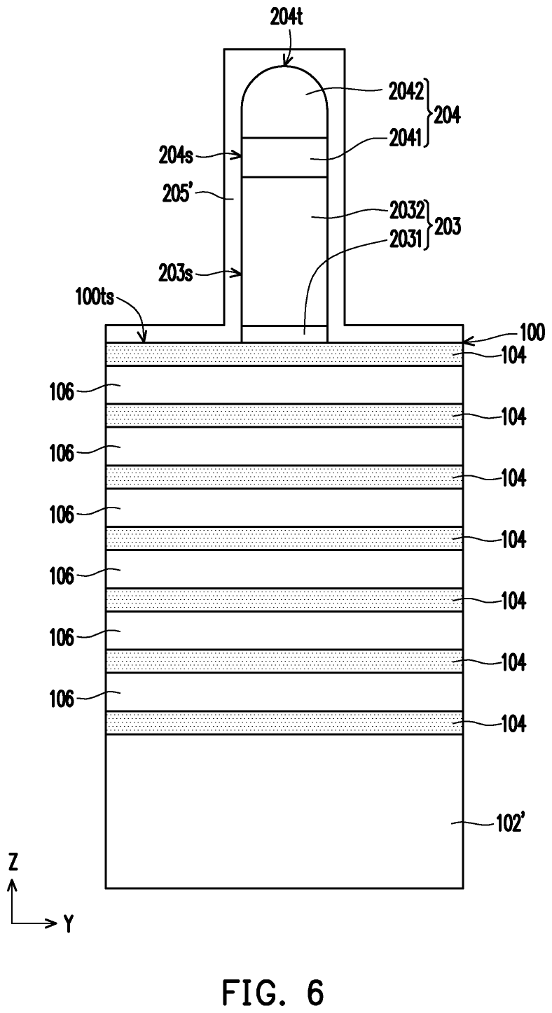

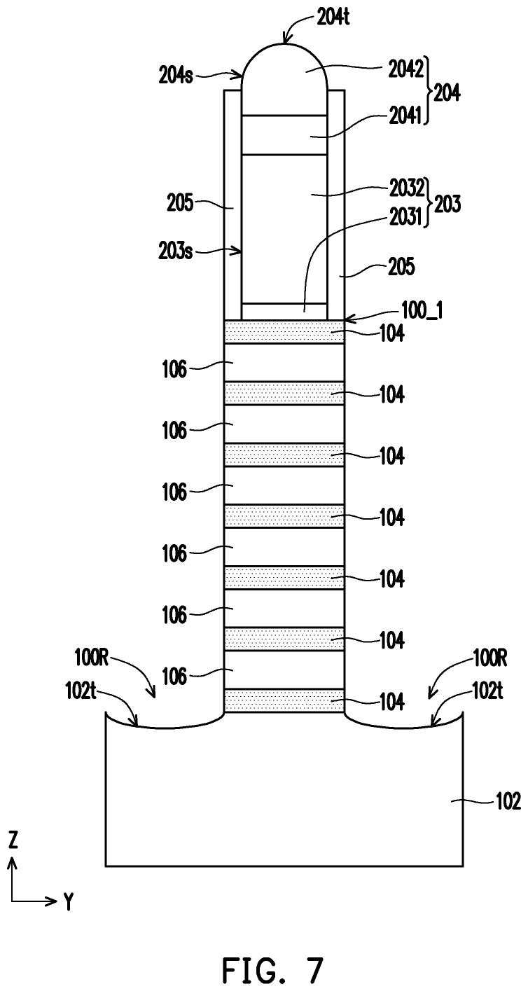

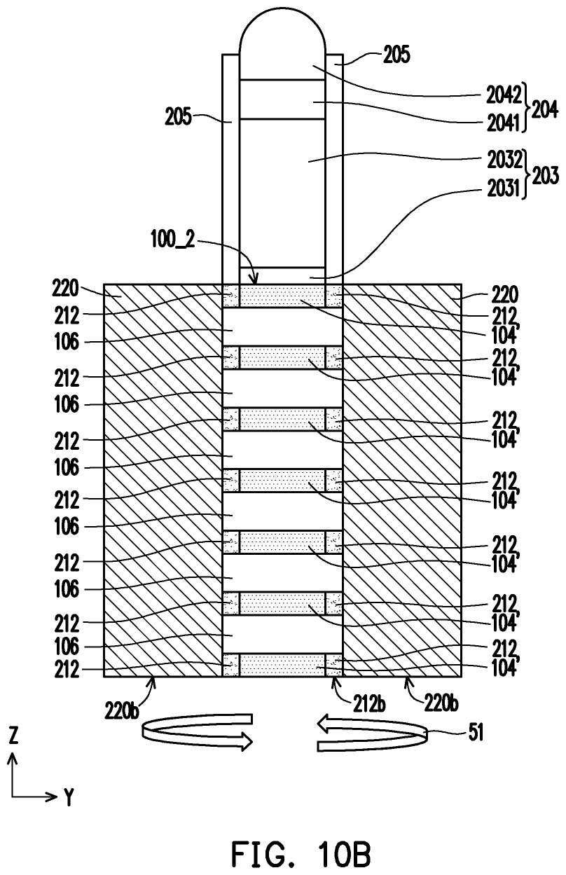

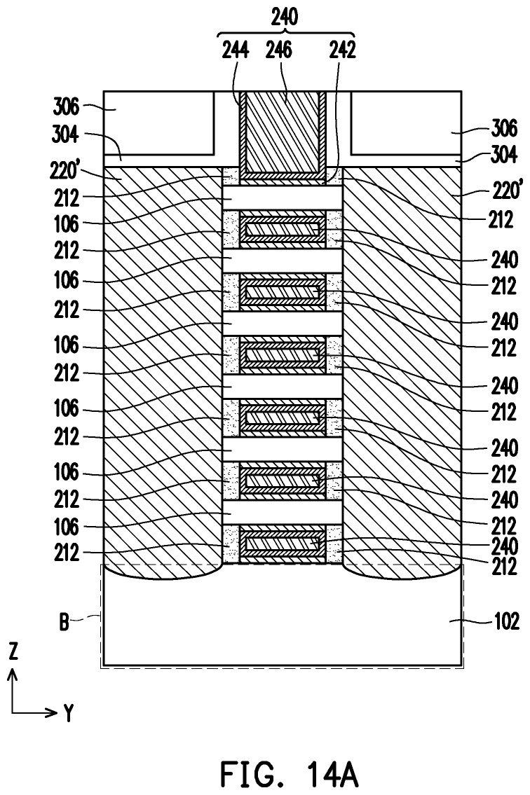

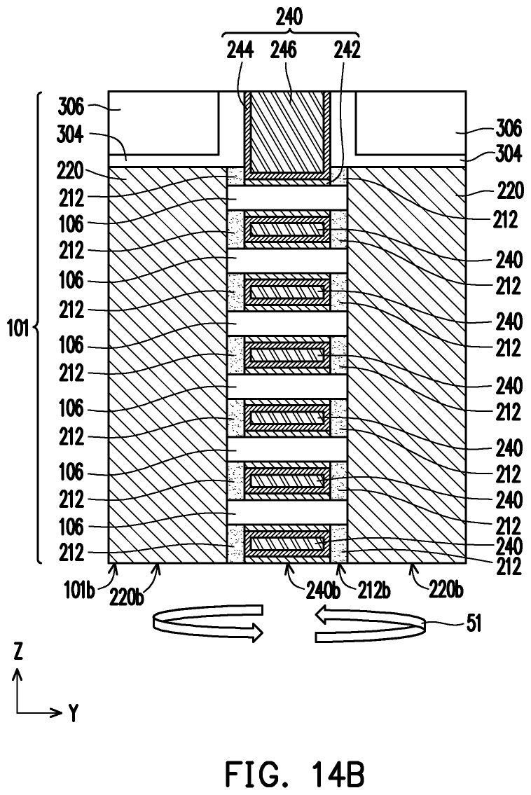

FIGS. 1 through 17 illustrate schematic perspective views and cross-sectional views of intermediate steps during a process for forming a semiconductor device, in accordance with some embodiments. For clarity of illustrations, in the drawings are illustrated the orthogonal axes (X, Y and Z) of the Cartesian coordinate system according to which the views are oriented. It should be understood that FIG. 5 is a cross-sectional view of the structure illustrated in FIG. 4 along the Y-direction (e.g., taken along the line A-A of FIG. 4), and FIGS. 6 through 17 are cross-sectional views illustrating the following steps of the process for forming a semiconductor device. In addition, FIGS. 10B and 14B are schematic cross-sectional views of optional steps during a process for forming a semiconductor device, as will be discussed in greater detail below.

Referring to FIG. 1, a stack of first semiconductor layers 104 and second semiconductor layers 106 may be formed on a semiconductor substrate 102′. In some embodiments, the semiconductor substrate 102′ includes a crystalline silicon substrate or a bulk silicon substrate (e.g., wafer). In some embodiments, the semiconductor substrate 102′ is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102′ includes a SOI substrate. The semiconductor substrate 102′ may include various doped regions (not individually shown) doped with p-type or n-type dopants, where the doped regions may be configured for an n-type FET, or alternatively, configured for a p-type FET.

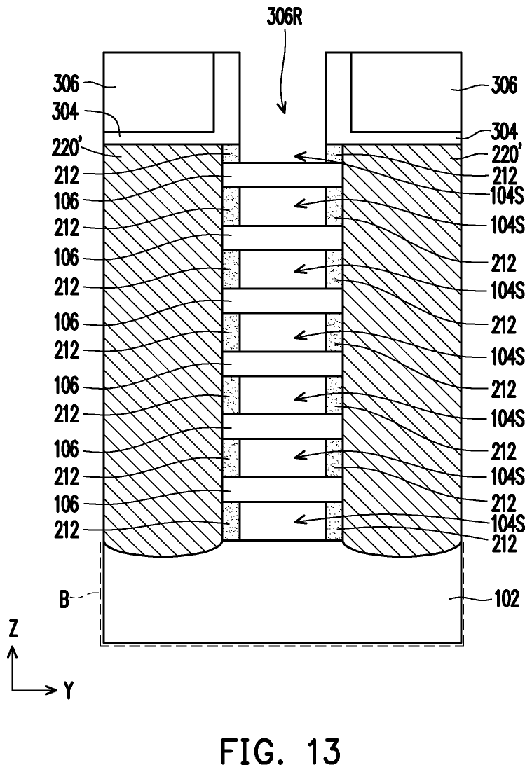

The first semiconductor layers 104 and the second semiconductor layers 106 may be alternately stacked upon one another (e.g., along the Z direction) to form a stack. The first semiconductor layers 104 may be considered sacrificial layers in the sense that they are removed in the subsequent process (see FIG. 13). In some embodiments, the bottommost one of the first semiconductor layers 104 is formed on the semiconductor substrate 102′, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102′), and either the first semiconductor layer 104 or the second semiconductor layer 106 may be the topmost layer (or the layer most distanced to the semiconductor substrate 102′). The disclosure is not limited by the number of stacked semiconductor layers.

The first semiconductor layers 104 and the second semiconductor layers 106 may have different materials (or compositions) that may provide for different oxidation rates and/or different etch selectivity between the layers. For example, the second semiconductor layers 106 are formed of the same material as the semiconductor substrate 102′, while the first semiconductor layers 104 may be formed of a different material which may be selectively removed with respect to the material of the semiconductor substrate 102′ and the second semiconductor layers 106. In some embodiments, the material of the first semiconductor layers 104 includes silicon germanium. In some embodiments, the second semiconductor layers 106 include silicon, where each of the second semiconductor layers 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets and may be considered as channel regions in the subsequent processes. The terms “semiconductor nanosheets” and “channel regions” may be used interchangeably herein.

With continued reference to FIG. 1, a mask layer 202 may be formed over the topmost one of the stack, for example, on the topmost one of the first semiconductor layers 104. The mask layer may be a single layer or include more than one sublayer (e.g., a first mask sublayer 2021 overlying the topmost first semiconductor layer 104, a second mask sublayer 2022 overlying the first mask sublayer 2021, and a third mask sublayer 2023 overlying the second mask sublayer 2022). In some embodiments, each of the sublayers is formed of a semiconductor material similar to the material of first and second semiconductor layer 104 or 106 or is formed of different dielectric materials.

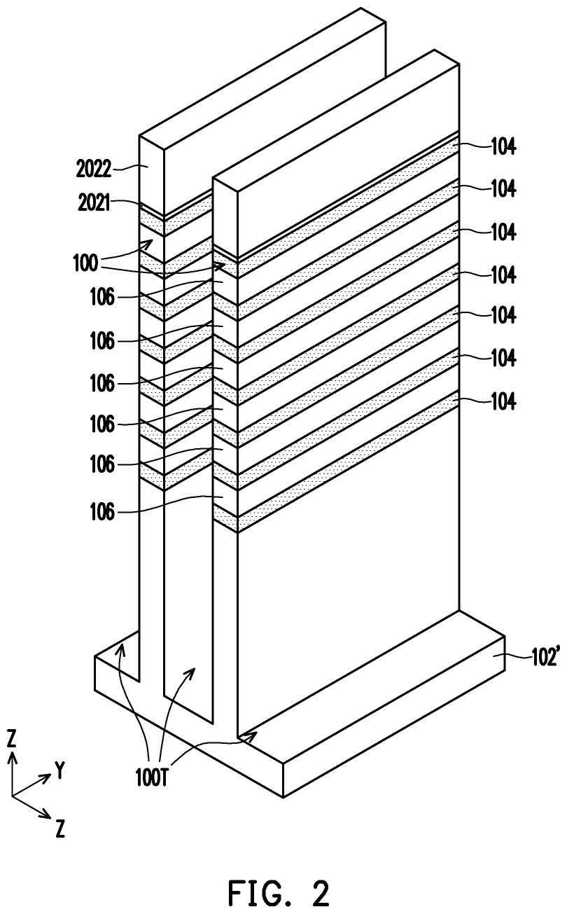

Referring to FIG. 2 and with reference to FIG. 1, a portion of the stack of first semiconductor layers 104 and second semiconductor layers 106 and the underlying portion of the semiconductor substrate 102′ may be removed to form trenches 100T, thereby defining a fin structure 100 between adjacent trenches 100T. Each trench 100T may be disposed between adjacent two of the fin structures 100 and may continuously extend along the Y-direction. The fin structure 100 may be formed by patterning the stack of first semiconductor layers 104 and second semiconductor layers 106 and the semiconductor substrate 102′ by using, e.g., lithography and etching, or other suitable techniques. The patterning process may use the mask layer 202 as a hard mask. For example, the mask layer 202 is initially patterned to have an elongated size along the X-direction with respect to the Y-direction, and then the mask layer is used to pattern exposed portions of the stack of first semiconductor layers 104 and second semiconductor layers 106 and the underlying semiconductor substrate 102′. For example, the fin structure 100 is formed by etching trenches 100T at exposed portions of the stack of first semiconductor layers 104 and second semiconductor layers 106 and the semiconductor substrate 102′. In some embodiments, the trenches 100T may be parallel strips (when viewed from the top) elongated along the Y-direction and distributed along the X-direction. The third mask sublayer 2023 of the mask layer 202 may be removed during or after the etching process. As shown in FIG. 2, the first mask sublayer 2021 and the second mask sublayer 2022 are patterned and left on the fin structures 100.

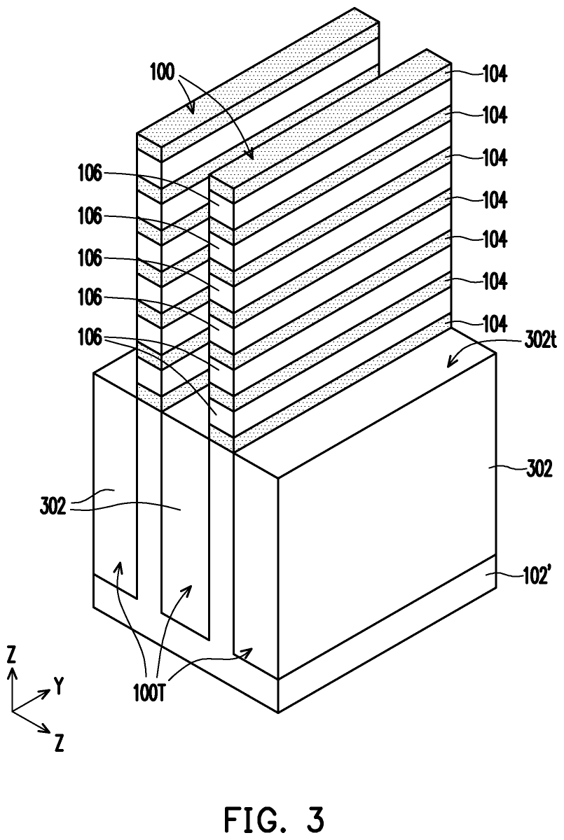

Referring to FIG. 3 and with reference to FIG. 2, a plurality of isolation structures 302 (also referred to as shallow trench isolation (STI) structures) may be formed in lower portions of the trenches 100T. For example, the isolation structures 302 extend at opposing sides of a lower portion of the semiconductor substrate 102′. In some embodiments, each of the isolation structures 302 is disposed between adjacent two of the fin structures 100 and covers a sidewall of a lower portion of the respective fin structure 100. The isolation structures 302 may be formed of an insulation material (e.g., an oxide, a Si-based oxide (e.g., SiOC, SiOCN, or the like), a nitride, the like, any other suitable material, or combinations thereof) which may electrically isolate neighboring fin structures 100 from each other.

In some embodiments, the isolation structures 302 are formed by initially depositing a layer of insulation material in the respective trench 100T and recessing the layer of insulation material using an acceptable etching process, such as one that is selective to the material of the isolation structures 302. During the recessing, the first mask sublayer 2021 and the second mask sublayer 2022 left on the fin structures 100 may serve as the etch masks. The isolation structures 302 may be recessed, and thus the fin structure 100 is protruded from the neighboring isolation structures 302. The top surfaces 302t of the isolation structures 302 may be a flat surface, a curved (e.g., convex or concave) surface, or combinations thereof, depending on the etching process. After (or during) the formation of the isolation structures 302, the first mask sublayer 2021 and the second mask sublayer 2022 may be removed from the fin structures 100, and the topmost first semiconductor layer 104 is then accessibly exposed.

Referring to FIGS. 4-5, a dummy gate structure 203 and a mask layer 204 overlying the dummy gate structure 203 may be formed on the fin structures 100. For example, the dummy gate structure 203 includes a dummy dielectric layer 2031 formed on the fin structures 100 and a dummy gate layer 2032 formed on the dummy dielectric layer 2031. In some embodiments, the dummy dielectric layer 2031 covers the top surfaces 302t of the isolation regions 302 and may extend between the dummy gate layer 2032 and the isolation regions 302. The dummy dielectric layer 2031 may be or include silicon oxide, silicon nitride, a combination thereof, or the like, and may be deposited or thermally grown according to acceptable techniques. The dummy gate layer 2032 may be a conductive or non-conductive material and may be selected from a group including amorphous silicon, polysilicon, poly-crystalline silicon-germanium, metallic oxides, and metals, and may be formed by using physical vapor deposition (PVD), chemical vapor deposition (CVD), sputtering, or other techniques.

The mask layer 204 may be formed on the dummy gate layer 2032. The mask layer 204 may be a single mask layer or include multiple sublayers formed of different materials including silicon nitride, silicon oxynitride, or the like. In the illustrated embodiment, the mask layer 204 includes a first mask sublayer 2041 overlying the dummy gate layer 2032 and a second mask sublayer 2042 overlying the first mask sublayer 2031. For example, a layer of mask material is initially formed and then patterned using acceptable photolithography and etching techniques to form the mask layer 204. Next, the pattern of the mask layer 204 may be transferred to the underlying dummy gate and dielectric materials to form the dummy gate layer 2032 and the dummy dielectric layer 2031, respectively. For example, the dummy gate structure 203 has a lengthwise direction along the X direction which is perpendicular to the lengthwise direction (e.g., the Y direction) of the respective fin structure 100.

Referring to FIG. 6 and with reference to FIG. 5, a dummy gate spacer layer 205′ may be formed over the structure illustrated in FIG. 5. In the Y-Z cross section, the dummy gate spacer layer 205′ may be formed on a top surface 204t and sidewalls 204s of the mask layer 204 and also formed on sidewalls 203s of the dummy gate structure 203. In some embodiments, the dummy gate spacer layer 205′ may extend across a portion of a top surface 100ts of the respective fin structure 100 which is not masked by the dummy gate structure 203. In the X-Z cross section (not shown), the dummy gate spacer layer 205′ may further extend to cover sidewalls of the respective fin structure 100. The dummy gate spacer layer 205′ may be a single layer or may include multiple sublayers formed of different materials including silicon oxide, silicon nitride, silicon oxynitride, or the like. The dummy gate spacer layer 205′ may be deposited by thermal oxidation or deposited by CVD, ALD, or the like.

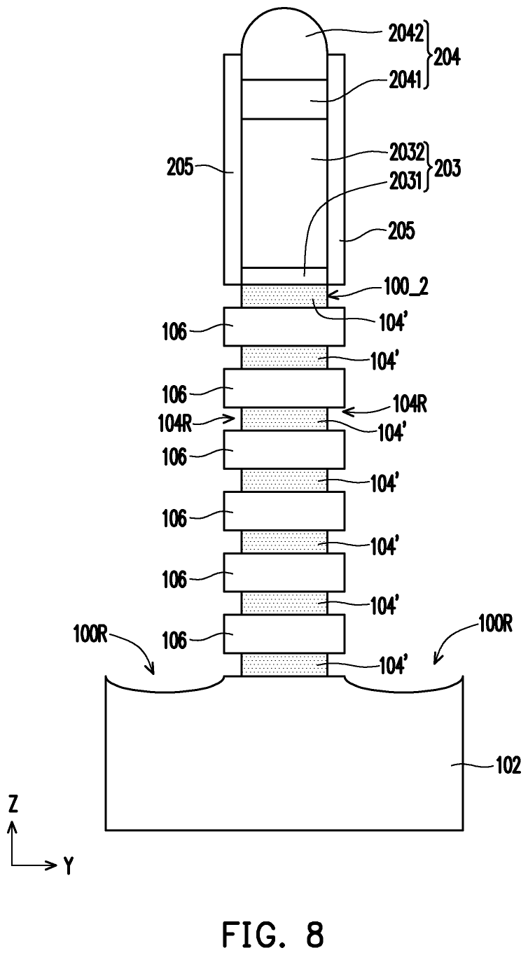

Referring to FIG. 7 and with reference to FIG. 6, a portion of the dummy gate spacer layer 205′ covering an upper portion of the mask layer 204 and top surface 100ts of the respective fin structure 100 may be removed to form a dummy gate spacer 205. The dummy gate spacer 205 may act to self-align subsequently formed source/drain (S/D) regions, as well as to protect sidewalls of the respective fin structure 100 during subsequent processing. For example, the dummy gate spacer layer 205′ is partially removed using an etching process, such as an isotropic etching process, an anisotropic etching process, or the like. After the etching, remaining portions of the dummy gate spacer layer 205′ forms the dummy gate spacer 205, where the dummy gate spacer 205 may be disposed on the sidewalls 203s of the dummy gate structure 203 and may extend to partially or fully cover sidewalls 204s of the mask layer 204. In some embodiments, the top surface 204t and the upper sidewalls of the second mask sublayer 2042 are exposed by the dummy gate spacer 205.

In some embodiments, a portion of the respective fin structure 100 directly underlying the dummy gate spacer layer 205′ and a portion of the semiconductor substrate 102′ underlying the portion of the respective fin structure 100 are removed to form recesses 100R and a respective etched fin structure 100_1 between two adjacent recesses 100R. S/D regions will be subsequently formed in the recesses 100R, and the recesses 100R may be referred to as S/D recesses. The recesses 100R may be formed by etching the dummy gate spacer layer 205′ overlying the top surface 100ts, the underlying fin structures 100, and the underlying semiconductor substrate 102′ using etching processes, such as anisotropic etching, or the like. A single etching process or multiple etching processes may be employed. The respective recess 100R may extend through the respective fin structure 100 to form the etched fin structure 100_1. In some embodiments, outer sidewalls of the dummy gate spacer 205 are substantially aligned with sidewalls of the etched fin structure 100_1. The respective recess 100R may further extend into the underlying semiconductor substrate 102′ to form a semiconductor substrate 102 having exposed top surfaces 102t. The top surfaces 102t of the semiconductor substrate 102 may be a flat surface, a curved (e.g., concave) surface, or combinations thereof, depending on the etching process.

Referring to FIG. 8 and with reference to FIG. 7, portions of the first semiconductor layers 104 exposed by the recesses 100R are removed in the lateral direction (e.g., the Y direction) to form a respective etched fin structure 100_2 having etched first semiconductor layers 104′. The removal may be performed by using, e.g., isotropic etching processes or the like. For example, the etchant of the selective etching process is chosen so that the portions of the first semiconductor layers 104 are removed to form lateral recesses 104R, while the second semiconductor layers 106 remain substantially intact during the etching. The respective etched first semiconductor layer 104′ may be laterally recessed from the sidewalls of the underlying (or overlying) second semiconductor layer 106. Although sidewalls of the etched first semiconductor layers 104′ adjacent the lateral recesses 104R are illustrated as being straight in FIG. 8, the sidewalls of the etched first semiconductor layers 104′ may be concave or convex.

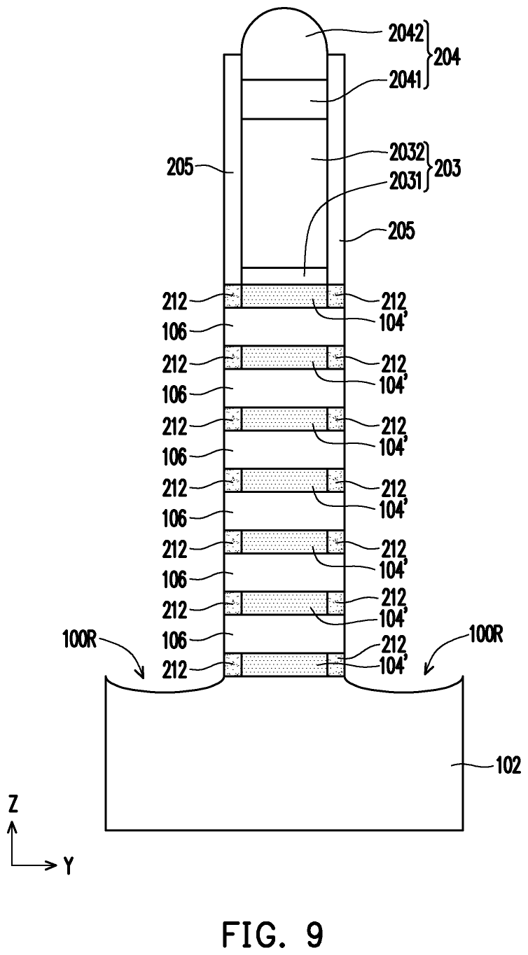

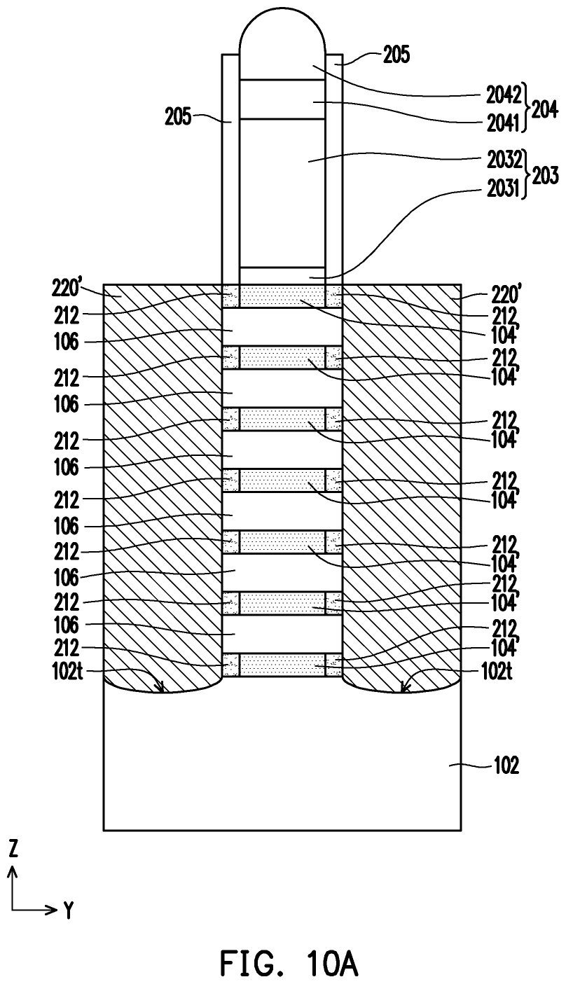

Referring to FIG. 9 and with reference to FIG. 8, inner spacers 212 may be formed in the lateral recesses 104R. For example, the inner spacers 212 are formed along the etched ends of each of the etched first semiconductor layers 104′ and along respective ends (along the Y-direction) of each of the etched first semiconductor layers 104′ and the second semiconductor layers 106. The inner spacers 212 may be formed of silicon nitride, silicon carbon-nitride, silicon-carbon-oxynitride, or any other type of dielectric material, and may be deposited using, e.g., a conformal deposition process and subsequent etching back to remove excess spacer material on the sidewalls of the etched fin structure 100_2 and on a surface of the semiconductor substrate 102. In some embodiments, the inner spacers 212 are formed of a material different from the dummy gate spacer 205. The dummy gate spacer 205 may serve as an etch mask when removing excess spacer material, and thus the outer sidewall of the dummy gate spacer 205 may be substantially aligned with outer sidewalls of the underlying second semiconductor layers 106 and outer sidewalls of the inner spacers 212.

Referring to FIG. 10A and with reference to FIG. 9, epitaxial structures 220′ may be formed in the recesses 100R using a process such as CVD, ALD, or the like. Each epitaxial structure 220′ may include silicon germanium, indium arsenide, indium gallium arsenide, indium antimonide, germanium arsenide, germanium antimonide, indium aluminum phosphide, indium phosphide, any other suitable material, or combinations thereof. The epitaxial structures 220′ may be doped with a conductive dopant to form S/D regions. It should be noted that S/D region(s) may refer to a source or a drain, individually or collectively dependent upon the context. In addition, the terms “epitaxial structures” and “S/D regions” may be used interchangeably herein. In some embodiments, the epitaxial structures 220′ are formed on the exposed top surfaces 102t of the semiconductor substrate 102, and the epitaxial structures 220′ are coupled to the outer sidewalls of the second semiconductor layers 106 and the inner spacers 212 along the Y-direction.

The epitaxial structures 220′ grown on the semiconductor substrate 102 may have a bottom surface conformally coupled to the exposed top surfaces 102t of the semiconductor substrate 102. In some embodiments where the semiconductor substrate 102 has a concave top surface, the bottom surface of the respective epitaxial structure 220′ may be a convex surface corresponding to the exposed top surfaces 102t. Although the upper surfaces of the epitaxial structures 220′ are illustrated as planar surfaces in the Y-Z cross section, it should be understood that in the perspective view, the upper surfaces of the epitaxial structures 220′ have facets which expand laterally outward along the Y direction beyond the sidewalls of the dummy gate structures 203. Each dummy gate structure 203 may be disposed between respective neighboring pairs of the epitaxial structures 220′. The dummy gate spacer 205 may be used to separate the epitaxial structures 220′ from the dummy gate structure 203 by a lateral distance so that the epitaxial structures 220′ do not short out with subsequently formed gate structures.

The epitaxial structures 220′ epitaxially grown on the exposed top surface 102t of the semiconductor substrate 102 without any dielectric/isolation layer blocking the top surface 102t may provide substantially defect-free epitaxial features. In a case where an isolation layer is formed on the top surface of the semiconductor substrate in the S/D recess for prevention of leakage, the epitaxial structures will grow on sidewalls of the channel regions and such sidewall growing results in defects (e.g., void formation and/or stacking fault) in the epitaxial structures. Such defects severely affect the device performance. In the depicted embodiment, the epitaxial structures 220′ grown on both of the exposed top surface 102t of the semiconductor substrate 102 and the sidewalls of the second semiconductor layers 106 may advantageously reduce or prevent the defects formed in the epitaxial structures 220′, thereby improving the resulting device performance and yield.

Referring to FIG. 10B and with reference to FIG. 10A, a planarization process 51 is optionally performed on the semiconductor substrate 102 after the formation of the epitaxial structures 220′. The planarization process 51 may include chemical mechanical polishing (CMP), grinding, etching back, combinations thereof, or the like. After the planarization process 51, the semiconductor substrate 102 may be fully removed, and the bottom surfaces 220b of the epitaxial structures 220 may be substantially leveled (e.g., coplanar) with the bottom surface 212b of the bottommost inner spacer 212, within process variations. It should be understood that the planarization process 51 is not limiting in this order and can be altered in alternative embodiments.

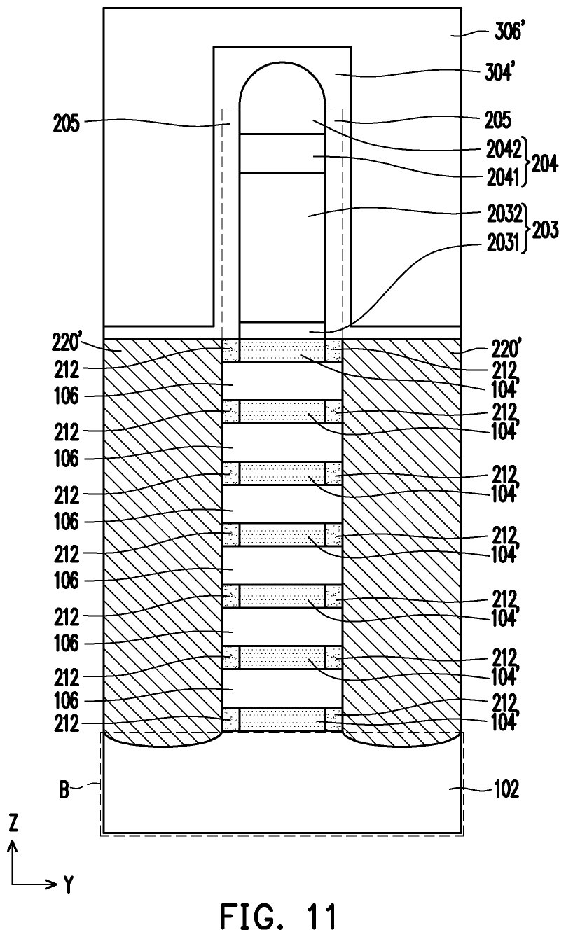

Referring to FIG. 11 and with reference to FIG. 10A or FIG. 10B, a first interlayer dielectric (ILD) material layer 306′ may be formed over the structure illustrated in FIG. 10A or FIG. 10B. The first ILD material layer 306′ may be formed of a dielectric material including phosphosilicate glass (PSG), borosilicate glass (BSG), boron-doped phosphosilicate glass (BPSG), undoped silicate glass (USG), or the like, and may be deposited by any suitable method, such as CVD, plasma-enhanced CVD (PECVD), or the like. In some embodiments, an etch stop material layer 304′ is disposed between the first ILD material layer 306′ and the epitaxial structures 220′, the mask layer 204, and the dummy gate spacer 205. The etch stop material layer 304′ may include a dielectric material (e.g., silicon nitride, silicon oxide, silicon oxynitride, or the like), and may have a different etch rate than the material of the overlying first ILD material layer 306′. In some embodiments, the etch stop material layer 304′ and the dummy gate spacer 205 are of the same material, and thus no visible interface therebetween. In some other embodiments, the planarization process 51 described in FIG. 10B is performed after the formation of the first ILD material layer 306′, and thus for purposes of illustration, the dashed box B indicates that the bottom portion of the structure in FIG. 11 may be removed at this stage.

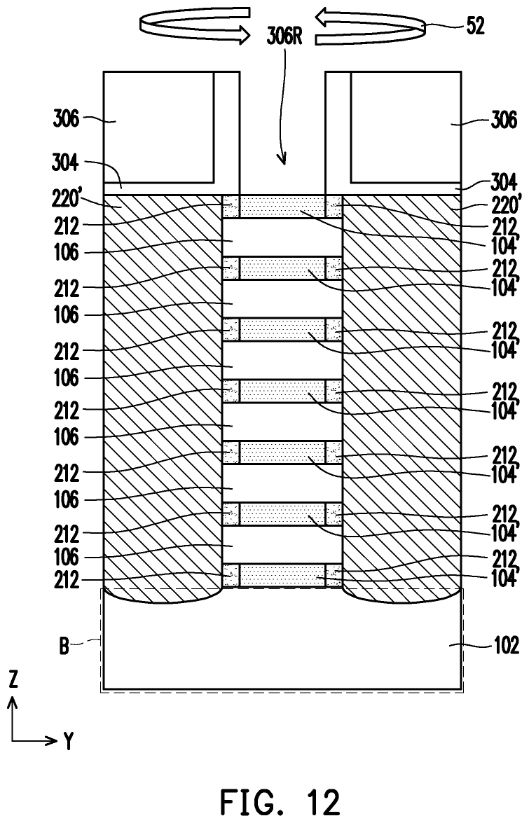

Referring to FIG. 12 and with reference to FIG. 11, a planarization process 52 may be performed on the first ILD material layer 306′, and then a removal process may be performed to remove the dummy gate structure 203 so as to form a recess 306R accessibly revealing the topmost etched first semiconductor layer 104′. The planarization process 52 may include CMP, grinding, etching back, combinations thereof, or the like. In some embodiments, the planarization process 52 removes upper portions of the first ILD material layer 306′ and the etch stop material layer 304′ and also removes the mask layer 204 and an upper portion of the dummy gate spacer 205 lining the sidewalls of the mask layer 204. The removal process may include one or more etching steps. For example, the etching step(s) using reaction gas(es) that selectively etch the dummy structure 203 at a faster rate than the first ILD material layer 306′, the etch stop material layer 304′, or the dummy gate spacer 205.

After the planarization process 52 and the removal process, the first ILD layer 306 and the etch stop layer 304 are formed. In some embodiments where the etch stop material layer 304′ and the dummy gate spacer 205 are of the same material, no visible interface is formed between the etch stop layer 304 and the dummy gate spacer 205, and thus in the following drawings the etch stop layer 304 and the dummy gate spacer 205 are illustrated as a single layer. In some other embodiments, the planarization process 51 described in FIG. 10B is performed after the formation of the first ILD layer 306 and the recess 306R, and thus for purposes of illustration, the dashed box B indicates that the bottom portion of the structure in FIG. 12 may be removed at this stage.

Referring to FIG. 13 and with reference to FIG. 12, the etched first semiconductor layers 104′ may be removed by etching (e.g., isotropic etching or the like). For example, using etchants which are selective to the materials of the etched first semiconductor layers 104′, while the second semiconductor layers 106, the first ILD layer 306, the etch stop layer 304, and the inner spacers 212 remain relatively un-etched as compared to the etched first semiconductor layers 104′. During the removal process, the first ILD layer 306 and the etch stop layer 304 may protect the epitaxial structures 220′. After the removal of the etched first semiconductor layers 104′, respective bottom and top surfaces of each second semiconductor layers 106 and the top surface of the semiconductor substrate 102 may be exposed by recesses 104S. In some other embodiments, the planarization process 51 described in FIG. 10B is performed after the removal of the etched first semiconductor layers 104′, and thus for purposes of illustration, the dashed box B indicates that the bottom portion of the structure in FIG. 13 may be removed at this stage.

Referring to FIG. 14A and with reference to FIG. 13, a respective gate structure 240 may be formed around the second semiconductor layers 106 and fills the recesses 306R and 104S. The respective gate structure 240 may include a gate dielectric layer 244 and a gate metal layer 246 wrapping around each second semiconductor layer 106 with the gate dielectric layer 244 disposed therebetween, where the second semiconductor layers 106 (also referred to as semiconductor nanosheets or semiconductor channel layers) function as channel regions. The gate dielectric layer 244 may be a single high-k dielectric material or may include a stack of multiple high-k dielectric materials. Other suitable dielectric material(s) may be used to form the gate dielectric layer 244.

The gate metal layer 246 may include a number of sections abutted to each other along the Z-direction, each of the gate metal sections may extend not only along a horizontal plane (e.g., the X-Y plane), but also along a vertical direction (e.g., the Z-direction), and thus two adjacent ones of the gate metal sections may adjoin together to wrap around a corresponding one of the second semiconductor layers 106, with the gate dielectric layer 244 disposed therebetween. The gate metal layer 246 may include a stack of multiple metal materials. For example, one or more work function sublayers are interposed between the gate dielectric layer 244 and the gate metal layer 246, wherein the work function sublayers may be formed separately for the n-type FET and the p-type FET which may use different metal layers.

In some embodiments, the respective gate structure 240 may include an interfacial layer 242 formed between each second semiconductor layer 106 and the gate dielectric layer 244 and between the semiconductor substrate 102 and the bottommost gate dielectric layer 244. In the Y-Z cross section, the interfacial layer 242 may be formed on the top and bottom surfaces of each second semiconductor layer 106 and on the top surface of the semiconductor substrate 102, and then the gate dielectric layer 244 is formed on the interfacial layer 242 and also formed on the sidewalls of the inner spacers 212. Subsequently, the gate metal layer 246 including the word function sublayer(s) and the filled metallic sublayer may be formed in the rest space of the recesses 306R and 104S. In some embodiments, after sequentially depositing the materials of the gate structures 240, excess materials of the gate structure 240 may be removed by a planarizing process, so that the top surface of the topmost gate structure 240 is substantially leveled (e.g., coplanar) with top surfaces of the first ILD layer 306 and the etch stop layer 304, within process variations.

Referring to FIG. 14B and with reference to FIG. 14A, in some embodiments, the planarization process 51, as described in FIG. 10B, is performed after the formation of the gate structure 240. For example, the structure in the dashed box B outlined in FIG. 14A is removed to form the epitaxial structures 220 having planarized bottom surfaces 220b, and the bottommost gate structure 240 and the inner spacers 212 around the bottommost gate structure 240 may be accessibly revealed after the planarization process 51. In some embodiments, the bottom surfaces 220b of the epitaxial structures 220 are substantially leveled (e.g., coplanar) with the bottom surface 240b of the bottommost gate structure 240 and the bottom surfaces 212b of the inner spacers 212, within process variations. There may be planarized marks (not shown; e.g., polishing marks) left on at least one of the bottom surfaces 220b of the epitaxial structures 220, the bottom surface 240b of the bottommost gate structure 240, and the bottom surfaces 212b of the inner spacers 212, as a result of the planarization process 51.

In some embodiments, the structure shown in FIG. 14B may be referred to as a device layer 101 which includes a plurality of active devices. The device layer 101 may include the epitaxial structure 220 (e.g., S/D regions), the second semiconductor layers 106 (e.g., the channel regions), and the gate structures 240. A back side 101b of the device layer 101 including the bottom surfaces (e.g., 220b, 240b, 212b) of the epitaxial structures 220, the bottommost gate structure 240, and the bottommost inner spacers 212 may be planarized. Although the device layer 101 in FIG. 14B is described as including nano-FETs, other embodiments may include device layers including different types of transistors, such as planar FETs, FinFETs, thin film transistors (TFTs), or the like.

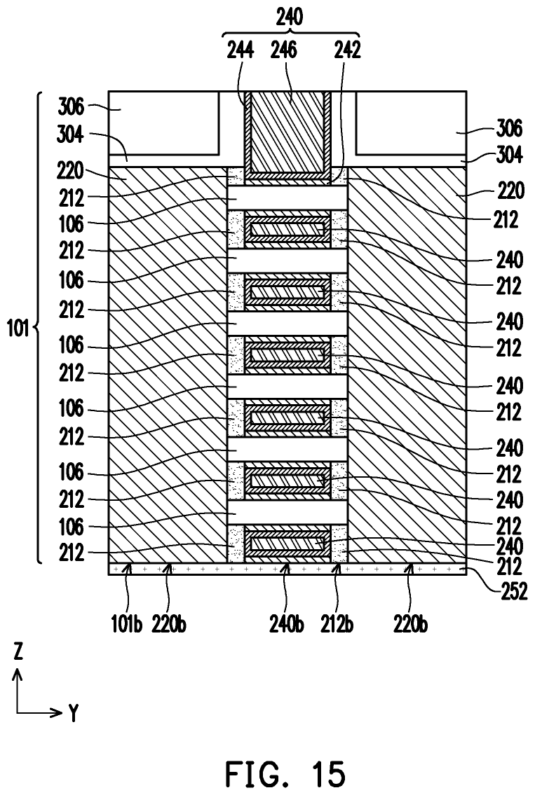

Referring to FIG. 15 and with reference to FIG. 14B, a first bonding sublayer 252 may be formed on the back side 101b of the device layer 101. The first bonding sublayer 252 may be formed of a Si-based material, such as Si, SiOx, SixNy, SiOC:H, SiCO:H, SiONC:H, SiOCN:H, SINC:H, SiCN:H, SINCO:H, a combination thereof, or the like, and may be formed using suitable technique, including PVD, CVD, variants thereof, the like, or combinations thereof. For example, the first bonding sublayer 252 is in physical contact with the bottom surfaces 220b of the epitaxial structures 220. In some embodiments, the first bonding sublayer 252 is also in physical contact with the bottom surface 240b of the bottommost gate structure 240 and the bottom surfaces 212b of the inner spacers 212.

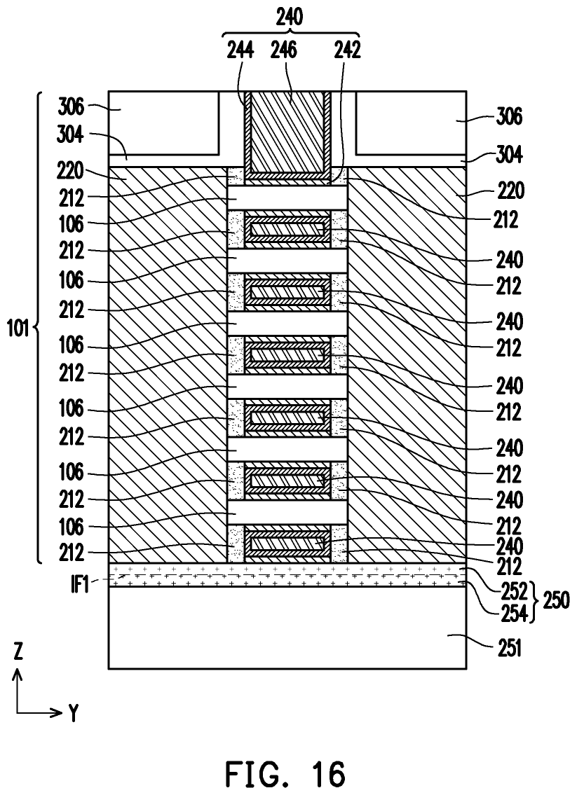

Referring to FIG. 16 and with reference to FIG. 15, a carrier substrate 251 may be provided with a second bonding sublayer 254, where the second bonding sublayer 254 may be formed of a material the same as (or similar to) the material of the first bonding sublayer 252. In some embodiments, the carrier substrate 251 is bonded to the structure shown in FIG. 15 through the second bonding sublayer 254. The carrier substrate 251 may be a wafer (e.g., a silicon wafer), a glass carrier substrate, a ceramic carrier substrate, or the like. In some embodiments, the carrier substrate 251 includes a substrate having STI regions (not shown) formed in/on the substrate, and the second bonding sublayer 254 disposed over the STI regions and the substrate. The carrier substrate 251 may have more elements disposed underlying the second bonding sublayer 254 and may provide structural support during the bonding and in the completed device. In some embodiments, the process previously described in FIGS. 1 through 16 are performed at wafer level, the carrier substrate 251 with the second bonding sublayer 254 formed thereon may be provided in a wafer form, and thus wafer-level bonding is performed at this stage.

In some embodiments, a bonding process is performed to form bonds between the bonding surfaces of the first bonding sublayer 252 and the second bonding sublayer 254. For example, the bonding process includes applying a surface treatment to one or more of the first bonding sublayer 252 and the second bonding sublayer 254. The surface treatment may include a plasma treatment. After the plasma treatment, the surface treatment may further include a cleaning process that may be applied to one or more of the first bonding sublayer 252 and the second bonding sublayer 254. Next, the carrier substrate 251 may be aligned with the structure in FIG. 15 and the two are pressed against each other to initiate a pre-bonding of the carrier substrate 251 to the structure in FIG. 15. After the pre-bonding, an annealing process is optionally performed. Once the bonding process is complete, dielectric-to-dielectric bonds, such as oxide-to-oxide bonds, may be formed at the interface IF1 between the first bonding sublayer 252 and the second bonding sublayer 254.

The first bonding sublayer 252 and the second bonding sublayer 254 may be collectively viewed as a bonding layer 250. In an embodiment where the first and second bonding sublayers are of the same material, no visible interface is formed in the bonding layer 250 after the bonding. In an embodiment where the first and second bonding sublayers are of the different materials, bonds (e.g., Si-to-SiOx, Si-to-SixNy, etc.) are formed at the interface IF1. The bonding layer 250 may act as a bottom isolation layer underlying the epitaxial structures 220, the bottom gate structure 240, and the bottom inner spacers 212. The bonding layer 250 may have a planar bottom surface facing the carrier substrate 251 and a planar top surface facing the epitaxial structures 220, the bottom gate structure 240, and the bottom inner spacers 212. Separately providing the device layer 101 and the carrier substrate 251 and bonding the device layer 101 to the carrier substrate 251 through the bonding layer 250 may be able to enlarge the process window (e.g., the thermal budget) of the device fabrication.

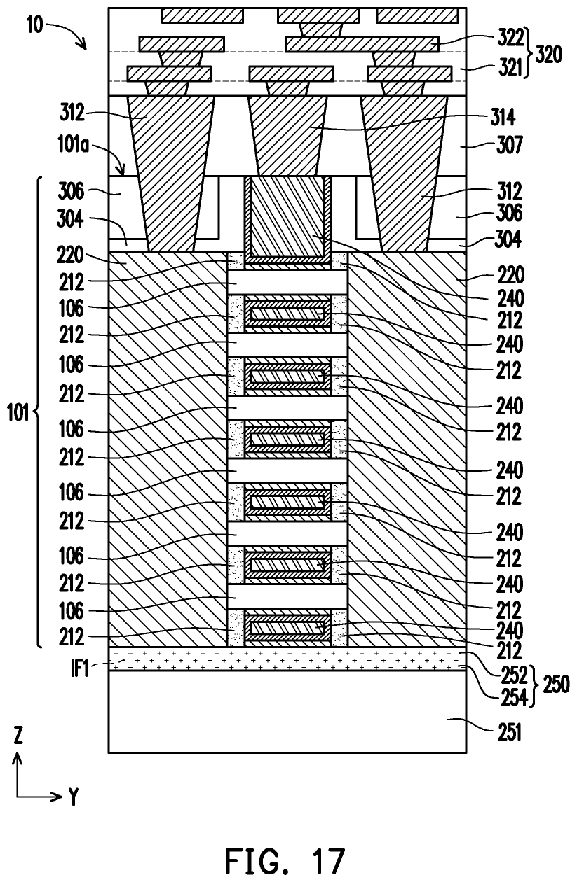

Referring to FIG. 17 and with reference to FIG. 16, a second ILD layer 307 may be formed on the first ILD layer 306. In some embodiments, S/D contacts 312 are formed to extend through the second ILD layer 307 and the underlying first ILD layer 306 so as to be electrically coupled to the epitaxial structures 220. A gate contact 314 may be formed to extend through the second ILD layer 307 so as to be electrically coupled to the topmost gate structure 240. The second ILD layer may be formed of a dielectric material such as PSG, BSG, BPSG, USG, or the like, and may be deposited by any suitable method, such as CVD, PECVD, or the like. In some embodiments, a layer of second ILD material may be initially formed on the first ILD layer 306 and then patterned to form first recesses revealing the epitaxial structures 220 and a second recess revealing the topmost gate structure 240. Next, one or more layers (e.g., barrier layers, diffusion layers, and conductive fill materials) may be formed in the first and second recesses of the second ILD layer 307 to form the S/D contacts 312 and the gate contact 314, respectively. In some embodiments, a planarization process may be performed to remove excess portions of the S/D contacts 312 and the gate contact 314, which excess portions are over top surfaces of the second ILD layer 307.

With continued reference to FIG. 17, a front-side interconnect structure 320 including interconnect wirings 322 formed in an interconnect dielectric layer 321 may be formed over a front side 101a of the device layer 101. The front-side interconnect structure 320 may be referred to as a back end of line (BEOL) interconnect structure. The interconnect dielectric layer 321 formed on the second ILD layer 307 may be a single material layer or include multiple sublayers having different materials. The material of the interconnect dielectric layer 321 may include a low-k dielectric material, an extra low-k (ELK) dielectric material, or the like, and the interconnect dielectric layer 321 may be formed using an appropriate process, such as, CVD, ALD, PVD, PECVD, or the like. The interconnect wirings 322 may include conductive lines and conductive vias interconnecting the layers of conductive lines, and may be formed through any acceptable process, such as, a damascene process, a dual damascene process, or the like. For example, the conductive vias may extend through the interconnect dielectric layer 321 to provide vertical connections between layers of the conductive lines, and the bottommost conductive vias of the interconnect wirings 322 may be in physical and electrical contact with the S/D contacts 312 and the gate contact 314. The front-side interconnect structure 320 may be electrically coupled to the epitaxial structures 220 and the gate structures 240 through the S/D contacts 312 and the gate contact 314, respectively, to form functional circuits.

The semiconductor device 10 shown in FIG. 17 may be a portion of a device wafer having a plurality of device die regions. The device wafer may be singulated to separate a device die from one another. The device die may be packaged in subsequent processing to form an integrated circuit package. The device die may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a MEMS controller (e.g., application specific integrated circuit (ASIC)), a signal processing die (e.g., digital signal processing (DSP) die), a front-end die (e.g., analog front-end (AFE) dies), the like, or combinations thereof. It should be noted that although FIGS. 1 through 17 are described as a series of acts, these acts are not limiting in that the order of the acts can be altered in other embodiments, and the methods disclosed are also applicable to other structures. In alternative embodiments, some acts that are illustrated and/or described may be omitted in whole or in part.

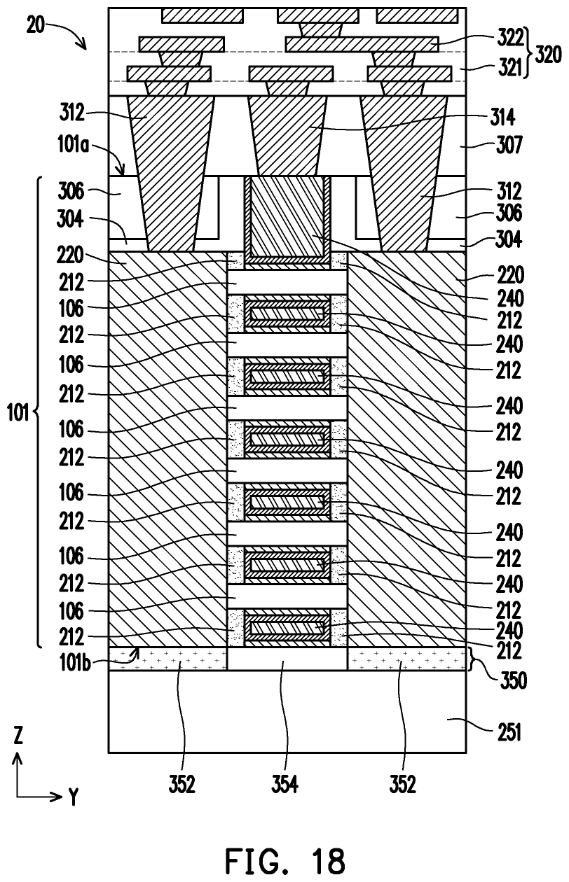

FIG. 18 illustrates a schematic cross-sectional view of a semiconductor device, in accordance with some embodiments. Unless specified otherwise, like reference numerals in this embodiment (and subsequently discussed embodiments) represent like components in the embodiment shown in FIGS. 1 through 17 formed by like processes. Accordingly, the process steps and applicable materials may not be repeated herein. The difference between the semiconductor device 20 shown in FIG. 18 and the semiconductor device 10 shown in FIG. 17 includes the bonding layer 350 formed between the carrier substrate 251 and the device layer 101.

In some embodiments, the bonding layer 350 at the back side 101b of the device layer 101 includes first segments 352 and a second segment 354 spatially separating the first segments 352 from one another. For example, the first segments 352 bond the epitaxial structures 220 to the carrier substrate 251, and the second segment 354 separates the bottommost gate structure 240 and the bottommost inner spacer 212 from the carrier substrate 251. Although a single second segment 354 is illustrated herein, more than one second segments 354 may be provided on the carrier substrate 251. The materials of the first segments 352 may be the same as (or similar to) the materials of the first and the second bonding sublayers described in FIG. 17. The second segment 354 may be formed of a material different from the first segments 352. The second segment 354 may be a dielectric bonding material. Alternatively, the second segment 354 is formed of a material same as the underlying carrier substrate 251. The first segments 352 may be viewed as partial isolation interposed between the epitaxial structures 220 and the carrier substrate 251.

According to some embodiments, a semiconductor device includes a device layer including a front side and a back side opposite to each other, a bonding layer disposed on the back side of the device layer, and a carrier substrate underlying the bonding layer. The device layer includes source/drain (S/D) structures, semiconductor channel layers connecting the S/D structures, and a gate structure disposed between the S/D structures and around each of the semiconductor channel layers, where the back side is planar and includes the S/D structures and the gate structure.

According to some alternative embodiments, a semiconductor device includes a bonding layer overlying a carrier substrate and a device layer overlying the bonding layer. The device layer includes semiconductor channel layers vertically separating apart from one another, a gate structure between adjacent two of the semiconductor channel layers, inner spacers disposed on opposite sidewalls of the gate structure, and source/drain (S/D) structures laterally abutting the semiconductor channel layers and the inner spacers, where an interface of bonding surfaces of the S/D structures and a bonding surface of the bonding layer is planar.

According to some alternative embodiments, a method of forming a semiconductor device includes forming a fin structure extending from a semiconductor substrate, wherein the fin structure comprises semiconductor channel layers alternatively spaced apart from one another with semiconductor sacrificial layers; growing epitaxial structures on exposed surfaces of the semiconductor substrate and the semiconductor channel layers, wherein the fin structure is interposed between the epitaxial structures; replacing the semiconductor sacrificial layers with a gate structure; planarizing the epitaxial structures to form source/drain (S/D) structures with planarized surfaces, wherein the semiconductor substrate is removed during the planarizing; and bonding the planarized surfaces of the S/D structures to a carrier substrate through a bonding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer comprising a front side and a back side opposite to each other, the device layer further comprising:
source/drain (S/D) structures;
semiconductor channel layers connecting the S/D structures; and
a gate structure disposed between the S/D structures and around each of the semiconductor channel layers, wherein the back side is planar and comprises the S/D structures and the gate structure;
a bonding layer disposed on the back side of the device layer; and
a carrier substrate underlying the bonding layer.

2. The semiconductor device of claim 1, wherein the back side of the device layer comprises bottom surfaces of the S/D structures and a bottom surface of the gate structure substantially coplanar with the bottom surfaces of the S/D structures.

3. The semiconductor device of claim 1, wherein the S/D structures and the gate structure are bonded to the carrier substrate through the bonding layer.

4. The semiconductor device of claim 1, wherein the bonding layer comprises first segments and a second segment separating the first segments from one another, and the S/D structures are bonded to the carrier substrate through the first segments.

5. The semiconductor device of claim 4, wherein the second segment is vertically interposed between the carrier substrate and the gate structure, and the first segments and the second segment are of different materials.

6. The semiconductor device of claim 1, wherein the back side of the device layer comprises planarized marks.

7. The semiconductor device of claim 1, wherein the device layer further comprises:
an inner spacer laterally separating the gate structure from the S/D structures, wherein the inner spacer is bonded to the carrier substrate through the bonding layer.

8. A semiconductor device, comprising:
a bonding layer overlying a carrier substrate; and
a device layer overlying the bonding layer and comprising:
semiconductor channel layers vertically separating apart from one another;
a gate structure between adjacent two of the semiconductor channel layers;
inner spacers disposed on opposite sidewalls of the gate structure; and
source/drain (S/D) structures laterally abutting the semiconductor channel layers and the inner spacers, wherein an interface of bonding surfaces of the S/D structures and a bonding surface of the bonding layer is planar.

9. The semiconductor device of claim 8, wherein a bottom surface of the gate structure is substantially coplanar with the bonding surfaces of the S/D structures.

10. The semiconductor device of claim 9, wherein the bottom surface of the gate structure is bonded to the carrier substrate through the bonding layer.

11. The semiconductor device of claim 8, wherein bottom surfaces of the inner spacers are substantially coplanar with the bonding surfaces of the S/D structures.

12. The semiconductor device of claim 11, wherein the bottom surfaces of the inner spacers are bonded to the carrier substrate through the bonding layer.

13. The semiconductor device of claim 8, wherein the bonding layer comprises first segments and a second segment separating the first segments from one another, and each of the S/D structures is bonded to the carrier substrate through one of the first segments.

14. The semiconductor device of claim 13, wherein the second segment is vertically interposed between the carrier substrate and the gate structure and is vertically interposed between the carrier substrate and the inner spacers.

15. A method of forming a semiconductor device, comprising:
forming a fin structure extending from a semiconductor substrate, wherein the fin structure comprises semiconductor channel layers alternatively spaced apart from one another with semiconductor sacrificial layers;
growing epitaxial structures on exposed surfaces of the semiconductor substrate and the semiconductor channel layers, wherein the fin structure is interposed between the epitaxial structures;
replacing the semiconductor sacrificial layers with a gate structure;
planarizing the epitaxial structures to form source/drain (S/D) structures with planarized surfaces, wherein the semiconductor substrate is removed during the planarizing; and
bonding the planarized surfaces of the S/D structures to a carrier substrate through a bonding layer.

16. The method of claim 15, wherein bonding the planarized surfaces of the S/D structures to the carrier substrate comprises:
forming a first bonding sublayer on the planarized surfaces of the S/D structures;
providing the carrier substrate with a second bonding sublayer;
bonding the first bonding sublayer to the second bonding sublayer to form the bonding layer, wherein an interface of the first bonding sublayer to the second bonding sublayer comprises dielectric-to-dielectric bonds.

17. The method of claim 15, wherein planarizing the epitaxial structures to form the S/D structures is performed prior to replacing the semiconductor sacrificial layers with the gate structure.

18. The method of claim 17, wherein when planarizing the epitaxial structures, the fin structure is planarized.

19. The method of claim 15, wherein planarizing the epitaxial structures to form the S/D structures is performed after replacing the semiconductor sacrificial layers with the gate structure.

20. The method of claim 19, wherein when planarizing the epitaxial structures, the gate structure is planarized.
